(19) United States
(12) Patent Application Publication
(10) Pub. No.: US 2012/0105061 A1
(43) Pub. Date: May 3, 2012

(54) Portable bio-magnetic imager and method

(75) Inventors: Christina Drake, Oviedo, FL (US); Clara R. Baleine, Orlando, FL (US)

(73) Assignee: LOCKHEED MARTIN CORPORATION, Bethesda, MD (US)

(21) Appl. No.: 12/801,799

(22) Filed: Jun. 25, 2010

Related U.S. Application Data
(60) Provisional application No. 61/213,624, filed on Jun. 25, 2009.

(51) Int. Cl. G01R 33/00

(52) U.S. Cl. 324/318

(57) ABSTRACT

Methods and apparatuses of the present invention perform imaging using a contrast agent and/or a metamaterials lens, together with a low magnetic field detector. The apparatus according to one embodiment comprises: a field source capable of generating a magnetic field directed to an area in a subject; a low magnetic field detector arranged downstream from the field source, the low magnetic field detector being capable of detecting a low magnetic field signature associated with the area in the subject; and a metamaterials lens arranged downstream from the field source, the metamaterials lens concentrating the magnetic field produced by the field source to the area in the subject, and/or concentrating back the magnetic signature from the area in the subject to the low magnetic field detector.

### CROSS REFERENCE TO RELATED APPLICATION

This non-provisional application claims priority under 35 U.S.C. §119(e) to U.S. Provisional Application No. 61/213,624 filed on Jun. 25, 2009, the entire contents of which are hereby incorporated by reference.

### BACKGROUND OF THE INVENTION

1. Field of the Invention

The present invention relates to an imaging technique and imaging apparatus, and more particularly to a method and apparatus for bio-imaging to detect injury or trauma.

2. Description of the Related Art

Traumatic Brain Injury (TBI) is considered to be the “signature wound” of modern wars such as the Iraq war. With the prevalence of Improvised Explosive Devices (IEDs) used by adversaries on the battlefield, undiagnosed mild to moderate TBI is likely to remain a significant problem for soldiers returning from combat. A main reason for undiagnosed TBI is the inability to quantify the damage to a soldier's brain soon after blast exposure. Currently a qualitative exam is given to a soldier, in the absence of obvious physical trauma. However, the qualitative exam is unlikely to detect mild to moderate TBI. The Glasgow Coma Scale (GCS) is a neurological scale that aims to provide an objective way of recording the conscious state of a person for initial as well as subsequent assessment and is used for both military and sports related injuries. However, the GCS is a manual approach and cannot reliably detect mild to moderate TBI.

Currently, there is no technique that is portable and can also give an early diagnosis of mild to moderate TBI. There are, in fact, no diagnostic devices that can detect brain injury within a few hours of the injury. With traditional MRI and CT imaging techniques, detection of mild to moderate TBI within 24 hours after exposure to trauma can be difficult to achieve, due to the relatively small injury size at start of injury or soon after injury, as compared to the large sampling size/volume of traditional imaging techniques, and because it takes more than 24 hours after exposure for brain damage to meet resolution of conventional MRI equipment which uses magnetic fields of the order of 3-5 Tesla.

A few portable low field MRI machines are available for analysis of extremities (elbows, heels). These systems cannot be used for brain imaging, for TBI diagnosis, or for full body imaging, and cannot detect details of superimposed organs. These systems also suffer from poor imaging quality and an inability to scan over a wide area of interest, as they have a low imaging volume. FIG. 12 illustrates the image acquisition for a conventional clinical MRI system, which uses a magnetic field source 520, a contrast agent 530 and a magnetic field/RF detector 540 (to detect medium to high Tesla magnetic fields). In this configuration, cooling and infrastructure are required to acquire an image, and they significantly increase the size and weight of the MRI system. Furthermore, the magnetic field/RF detector 540 has reduced sensitivity.

FIGS. 13A and 13B illustrate a portable MagneVu 1000® MRI system (FIG. 13A) and operating data for the MagneVu 1000® MRI system (FIG. 13B). While this portable version does not require the cooling or infrastructure that typical clinical MRIs require, its functionality is extremely limited. Traditional clinical MRI systems are limited by cryogenic cooling and magnetic shielding requirements, while state-of-the-art portable versions suffer from a lack of sensitivity and poor image quality. Some “mobile” systems require an automobile (i.e., moving truck). Traditional portable MRI systems have reduced sensitivity due to the fact that they operate at lower magnetic fields than what would be found in a hospital setting (typically in the 0.2-0.5 T range), as many of these systems use a permanent magnet as the source. The MRI signal is usually proportional to the magnetic field applied to the subject, so lower field MRIs have poorer signal to noise ratio. This conventional MRI system can only image dedicated extremities (only the knee, or only the arm), which reduces its shielding requirements. Because the portable system is only for dedicated extremities, no contrast agent is used, since the portable system cannot be used to image organs, which are usually obscured by other organs. The poor image quality of this conventional MRI device is also caused by the mechanism used to derive an image in current state-of-the-art MRI, whether low or high field. This mechanism uses a secondary gradient field to probe the patient for spatial information. This is also a problem in the conventional low field system, since a permanent magnetic field is susceptible to a field inhomogeneity, which affects the gradient used to reconstruct the image.

Disclosed embodiments of this application address these and other issues by providing methods and apparatuses for early detection of internal trauma, and especially for early detection of brain injury. The apparatuses of the present invention can be implemented as portable imaging devices and may use a sensor which detects low magnetic fields, in connection with a metamaterials lens. The methods and apparatuses of the present invention can be used for detection in other domains besides the medical field. For example, methods and apparatuses of the present invention can be used for magnetic imaging for border patrol and underwater vehicle sensing.

### SUMMARY OF THE INVENTION

The present invention is directed to imaging methods and apparatuses. According to a first aspect of the present invention, an Imager comprises: a field source capable of generating a magnetic field directed to a subject; a contrast agent applied to the subject, the contrast agent selectively seeking out an area in the subject, wherein the area also receives the magnetic field; and a low magnetic field detector arranged downstream from the field source, the low magnetic field detector being capable of detecting a low magnetic field associated with the area indicated by the contrast agent.

According to a second aspect of the present invention, an Imager comprises: a field source capable of generating a magnetic field directed to an area in a subject; a low magnetic field detector arranged downstream from the field source, the low magnetic field detector being capable of detecting a low magnetic field signature associated with the area in the subject; and a metamaterials lens arranged downstream from the field source, the metamaterials lens concentrating the magnetic field produced by the field source to the area in the subject, and/or concentrating back the magnetic signature from the area in the subject to the low magnetic field detector.

According to a third aspect of the present invention, an imaging method comprises: generating a magnetic field directed to a subject; indicating an area in the subject using a contrast agent including nanoparticles which selectively seek out the area in the subject; and detecting a low magnetic field associated with the area indicated by the contrast agent.

According to a fourth aspect of the present invention, an imaging method comprises: generating a magnetic field directed to an area in the subject; concentrating, using a metamaterials lens, the generated magnetic field to the area in the subject; and detecting a low magnetic field signature associated with the area in the subject.

### BRIEF DESCRIPTION OF THE DRAWINGS

Further aspects and advantages of the present invention will become apparent upon reading the following detailed description in conjunction with the accompanying drawings, in which:

FIG. 1 is a general block diagram of a Portable Bio-Magnetic Imager according to an embodiment of the present invention;

FIG. 2 is a block diagram illustrating a Portable Bio-Magnetic Imager according to an embodiment of the present invention illustrated in FIG. 1;

FIG. 3 is a block diagram of a Portable Bio-Magnetic Imager according to another embodiment of the present invention;

FIG. 4 is an exemplary Portable Bio-Magnetic Imager according to an embodiment of the present invention illustrated in FIG. 3;

FIG. 5 is a block diagram of a Portable Bio-Magnetic Imager according to another embodiment of the present invention;

FIG. 6 illustrates a sensor which operates at room temperature and is used as a detector component in a Portable Bio-Magnetic Imager according to embodiments of the present invention illustrated in FIGS. 1-5;

FIG. 7 illustrates a MEMS device including multiple cantilever devices for use in a Portable Bio-Magnetic Imager according to an embodiment of the present invention;

FIG. 8A illustrates imaging performance when a metamaterials lens is used according to an embodiment of the present invention, and FIG. 8B illustrates comparative imaging performance without a metamaterials lens;

FIGS. 8C and 8D illustrate wave propagation in a metamaterial lens used in a Portable Bio-Magnetic Imager according to an embodiment of the present invention;

FIGS. 9A, 9B, 9C and 9D illustrate an exemplary isotropic metamaterials lens for use in a Portable Bio-Magnetic Imager according to an embodiment of the present invention;

FIG. 9E illustrates details and performance of metamaterials lenses uses in a Portable Bio-Magnetic Imager according to an embodiment of the present invention;

FIGS. 10A and 10B illustrate calculated sensitivity of a standard surface coil without and with a metamaterial lens for use in a Portable Bio-Magnetic Imager according to an embodiment of the present invention;

FIGS. 11A and 11B illustrate the change in normalized magnetic field intensity with a change in distance from an object to be imaged with a metamaterials lens used in a Portable Bio-Magnetic Imager according to an embodiment of the present invention;

FIG. 12 illustrates a conventional MRI system employing a contrast agent; and

FIGS. 13A and 13B illustrate details of a portable MagneVu 1000® MRI system.

### DETAILED DESCRIPTION

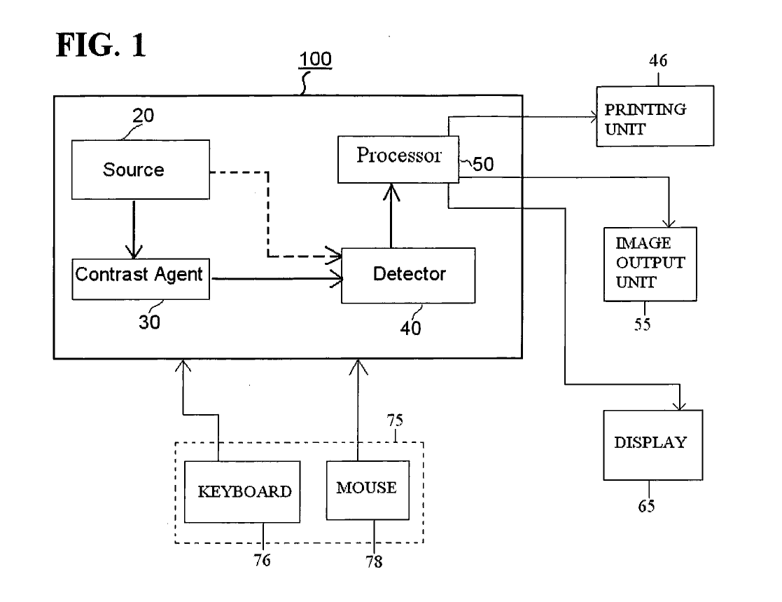

Aspects of the invention are more specifically set forth in the accompanying description with reference to the appended figures. FIG. 1 is a general block diagram of a Portable Bio-Magnetic Imager 100 according to an embodiment of the present invention. The system 100 illustrated in FIG. 1 includes the following components: a magnetic field source 20; a contrast agent 30; a magnetic field detector 40 and processor 50. Operation of the system 100 in FIG. 1 will become apparent from the following discussion.

The magnetic field source 20 generates electromagnetic radiation or an electromagnetic field which is applied to a region containing a contrast agent 30. The source 20 may be a permanent magnet coil, or some other device which produces a magnetic field through an electrical, magnetic, mechanic or other type(s)/combinations of mechanism(s).

The contrast agent 30 is applied to a subject (for example, a human) for detection of a signature of a certain type of anatomical change, or to a non-biological subject (i.e., when the Imager is used for magnetic imaging for border patrol or underwater vehicle sensing) for detection of a change in material character or materials characterization related to NMR. Each atomic nuclei (all materials) have a distinct signature that is largely unperturbed by surrounding environment. These distinct signatures can be detected when the signal-to-noise ration (SNR) is high enough to allow for interpretation of the signature. The contrast agent 30 may include various substances that have the property of selectively seeking out certain areas in a subject.

The detector 40 obtains detection data from the subject to which the contrast agent 30 is applied. The detector 40 may include electrical, magnetic and mechanic components, combination devices such as MEMS devices, magnetometers, magnetorestrictive devices, etc.

Processor 50 processes the data from detector 40 to output a graphical representation of an imaged subject area, or other type of reconstruction data. The processor 50 may include one or more microprocessors, purpose built hardware such as, for example, FPGA, ASIC, etc., software systems and applications, software packages, etc. Software packages that may be part of processor 50 may be recorded on a computer readable medium such as a memory device, RAM, CD/DVD/USB drives, etc., and/or may be part of a physical device such as one or more (micro)processors.

A user, e.g., a medical professional, may control parameters associated with the source 20, the contrast agent 30 and/or the detector 40 and may view the output of processor 50 via a display 65 or other device that produces representations of the output of processor 50, such as a printing unit 46 or an image output unit 55. The user may input commands to the Imager 100 via a user input unit 75. In the embodiment illustrated in FIG. 1, the user input unit 75 includes a keyboard 76 and a mouse 78, but other conventional input devices could also be used. Elements of the Portable Bio-Magnetic Imager 100 may also be controlled automatically.

The printing unit 46 receives the output of the processor 50 and generates a hard copy of the processed image data. In addition or as an alternative to generating a hard copy of the output of the processor 50, the processed image data may be returned as an image file, e.g., via a portable recording medium or via a network (not shown). The output of processor 50 may also be sent to image output unit 55 that performs further operations on image data for various purposes. The image output unit 55 may be a module that performs further processing of the image data, a database that collects and compares images, etc.

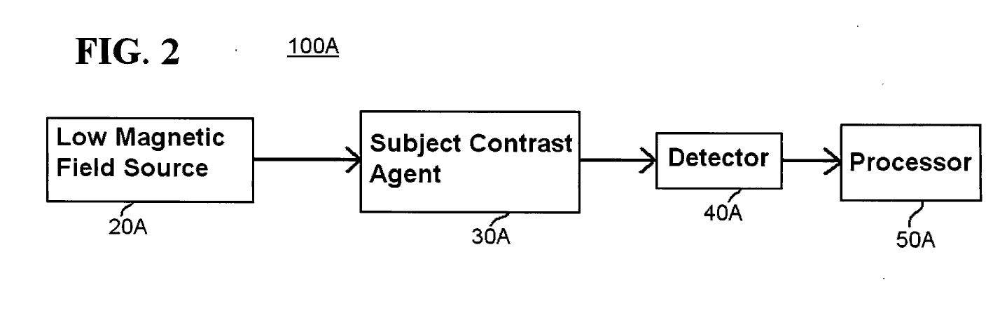

FIG. 2 is a block diagram illustrating a Portable Bio-Magnetic Imager 100A according to an embodiment of the present invention illustrated in FIG. 1. As shown in FIG. 2, the Portable Bio-Magnetic Imager 100A according to this embodiment includes: a low magnetic field source 20A; a subject contrast agent 30A; a detector 40A; and processor 50A. Although the various components of FIG. 2 are illustrated as discrete elements, such an illustration is for ease of explanation and it should be recognized that certain operations of the various components may be performed by the same physical device, e.g., by one or more microprocessors or devices.

Operation of Portable Bio-Magnetic Imager 100A will be next described in the context of Traumatic Brain Injury (TBI) detection. However, the principles of the current invention apply equally to detection of features in other organs besides the brain, as well as to detection of features in non-biological subjects.

The Portable Bio-Magnetic Imager of the present invention will give medics on the battlefield the ability to rapidly assess whether or not a soldier which has recently been exposed to a blast has internal neural signs of TBI. The Portable Bio-Magnetic Imager may use a small form factor such as, for example, a helmet. The Portable Bio-Magnetic Imager of the present invention may use a low field magnetic imaging technique that can be used in any location, with reduced packaging requirements for the imager device.

Generally, the arrangement of elements for the Portable Bio-Magnetic Imager 100A illustrated in FIG. 2 uses magnetic radiation from the low magnetic field source 20A, and the subject contrast agent 30A to produce a change/contrast in a subject such as a human. The low magnetic field source 20A may be a permanent magnet coil, or some other type of magnetic field source. The field detector 40A detects that change, and the results of detector 40A are processed by the processor 50A to detect mild to moderate TBI. The subject contrast agent 30A selectively seeks out damaged areas in a subject (i.e., in the brain of a wounded subject) and can be used as a pre-indicator of damage for earlier detection of mild to moderate TBI. The detector 40A detects low magnetic fields, such as, for example, sub-μT fields, μT fields or mT fields. The magnetic field source 20A pre-polarizes the atoms, for example, by aligning their protons. The magnetic field source 20A may pre-polarize the atoms of both the subject and the subject contrast agent 30A. The detector 40A can either detect a change in magnetic field (for example, by looking for resonance) or spatially map magnetic fields, while the contrast agent(s) 30A are used to highlight the damage in the subject's brain, so that damaged areas would show up as “bright” spots. The contrast agent 30A is acting as a highlighter or tag to damaged tissue. The change in magnetic fields, for example through resonance, is a function of the input field applied. In the exemplary case of mapping a static field, this change would be on the order of μT.

The subject contrast agent 30A may be a free radical scavenger. The Portable Bio-Magnetic Imager of the present invention may use engineered nanoparticles as the contrast agent 30A. The engineered nanoparticles selectively seek out damaged areas and can be used as pre-indicators of damage for earlier detection of mild to moderate TBI. The size of the magnetic imaging device using engineered nanoparticles is reduced in order to make the imager portable, for diagnosing injuries in any location, such as, for example, in a battlefield.

In order to enhance the ability to image and the ability to identify the first stages of damage from TBI, engineered doped Ceria nanoparticles may be used as the contrast agent 30A, in an exemplary embodiment. Other nanoparticles may also be used.

Ceria nanoparticles, which are used in an exemplary embodiment, are synthesized using a microemulsion process. The final characteristics of the nanoparticles are determined by the processing parameters of the synthesis process. Dopants for the nanoparticles may include Y, Sm, Gd, and Yb, but are not limited to these elements. In an exemplary embodiment, Ceria nanoparticles with a size of ˜2-20 nm are used as the contrast agent 30A.

Ceria nanoparticles have been shown to selectively search out damage in-vitro (for example, cancerous cells) due to their ability to behave as a free radical scavenger. Ceria nanoparticles have also been shown to exhibit this scavenging behavior after crossing the Blood-Brain-Barrier (BBB), which is critical for diagnosing head trauma. Due to this free radical scavenging behavior and the ability to cross the BBB, Ceria will be able to search out the beginning stages of mild to moderate TBI by congregating around injured tissue portions before injury becomes visible through normal imaging techniques, by searching out free radical oxygen.

Since Ceria nanoparticles have free radical scavenging characteristics and can search out damaged tissue, Ceria nanoparticles provide the ability to “see” the beginning stages of damage due to TBI, before the damaged area reaches the sampling size for imaging techniques (sub-μm). Therefore, engineered Ceria nanoparticles can target and highlight small areas of internal damage that would be visible through a magnetic imaging technique.

Exemplary nanoparticles that may be used as contrast agent in the Imager of the present invention are described in the following publications: “Vacancy Engineered Ceria Nanostructures for Protection from Radiation-Induced Cellular Damage”, by Tarnuzzer et al., Nanoletters, 2005, Vol. 5, No. 12, pp. 2573-2577; “Protein Adsorption and Cellular Uptake of Cerium Oxide Nanoparticles as a Function of Zeta Potential”, by Patil et al., Biomaterials, Vol. 28, November 2007, pp. 4600-4607; and “Electron Paramagnetic Study on Radical Scavenging Properties of Ceria Nanoparticles”, by Babu et al., Chemical Physics Letters 442 (2007), pp. 405-408, the entire contents of these publications being hereby incorporated by reference.

The detector 40A includes a detector component. The detector component may be a magnetometer device. The detector component may be a magnetorestrictive MEMS device, for example.

In an exemplary embodiment, the MEMS device is a cantilevered, thin film coated magnetorestrictive MEMS device. The thin film coated magnetorestrictive MEMS device may be a FeGa MEMS device, for example. The detector component device used in the present invention has performance comparable to that of a SQUID device used currently in low field MRI, but does not require the cryogenic cooling required by SQUID devices, thus reducing the power and cooling required to run the device. Magnetorestrictive sensors used in the present invention have shown room temperature sensitivity down to 10⁻⁷ to 10⁻¹⁰ Tesla.

Exemplary MEMS devices that may be used as the detector component are described in US Patent Application Publication 2007/0252593 A1 by Takeuchi et al. (U.S. Pat. No. 7,345,475), the entire contents of which are hereby incorporated by reference.

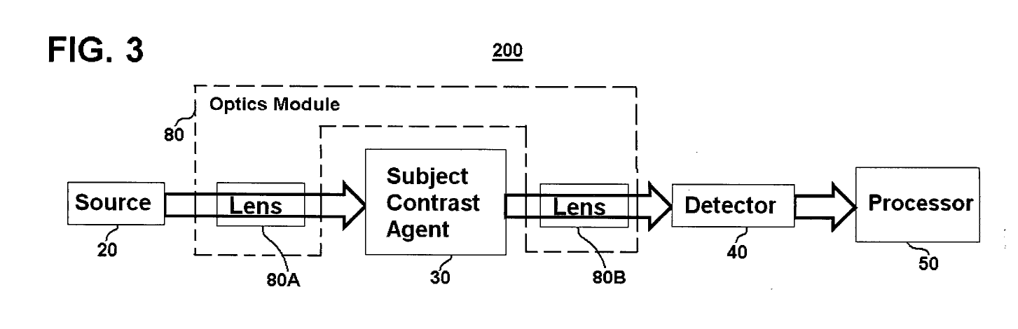

FIG. 3 is a block diagram of a Portable Bio-Magnetic Imager 200 according to another embodiment of the present invention. The system 200 illustrated in FIG. 3 includes the following components: a source 20; a subject contrast agent 30; a detector 40; an optics module 80; and a processor 50. The Portable Bio-Magnetic Imager 200 in FIG. 3 includes elements of the Portable Bio-Magnetic Imager 100 of FIG. 1, and further includes an optics module 80 which concentrates an electromagnetic field generated by source 20 to a subject, and may also concentrate back the electromagnetic signature from the subject to the detector 40.

The imaging enhancement and performance of the Portable Bio-Magnetic Imager can be increased using metamaterials. In a preferred embodiment, the Portable Bio-Magnetic Imager 200 includes an optics module 80 which incorporates one or more metamaterials lenses 80A and 80B to concentrate both the input and the output fields and decrease the need for shielding, subject proximity, and field strength, while maintaining imaging resolution.

A metamaterial lens is an engineered device which can achieve very high resolution. In an exemplary metamaterials lens, the refractive index (n) may be equal to minus one, or the magnetic permeability (mu) or the electric permittivity (epsilon) may be equal to minus one. A magnetic metamaterial lens acts as a magnetic focusing device into discrete areas in the body and can achieve super resolution through direct magnetic imaging. A metamaterials lens has many advantages including improved resolution, increased sensitivity, decreased acquisition time, and enhanced signal to noise ratio.

The metamaterials lens decreases the need for shielding due to its ability to concentrate the field into a subject, and then subsequently into the detector. This boosts the signal part of SNR (>5×) to overcome the noise component, where shielding works to decrease noise. The field strength can also be made lower for the same reason. By contrast, in traditional MRIs the signal is boosted by increasing the magnetic field strength.

Each atomic nuclei (all materials) have a distinct signature that is largely unperturbed by surrounding environment. The issue in detecting these distinct signatures (NMR) is being able to get enough signal-to-noise ratio (SNR) to interpret the signature. With a metamaterials lens, it is possible to detect such distinct signatures (through NMR, for example) by boosting the signal portion without the need for boosting the magnetic field, to obtain a high SNR to interpret the signature, thus enabling identification of biological changes, or non-biological materials and chemicals even when the materials and chemicals are embedded within other objects. In the case of non-biological materials and chemicals, a contrast agent is not used.

The use of the metamaterials lens improves performance and imaging enhancement of the Portable Bio-Magnetic Imager 200 over conventional MRI techniques in which an image is enhanced by increasing magnetic field strength and proximity to subject, and by using extensive shielding. The Imager 200 may have two or more metamaterials lenses 80A and 80B, one lens being placed between the source 20 and the subject contrast agent 30, and the other lens being placed between the subject contrast agent 30 and the detector 40, respectively. In another embodiment, the Imager may have only one metamaterials lens 80A placed between source 20 and subject contrast agent 30. In yet another embodiment, the Imager may have only one metamaterials lens 80B placed between subject contrast agent 30 and detector 40. Finally, in another embodiment, the Imager has only one metamaterials lens which is placed so as to both concentrate an ultra low magnetic field produced by source 20 to the subject, and concentrate back the magnetic signature from the subject to the detector 40.

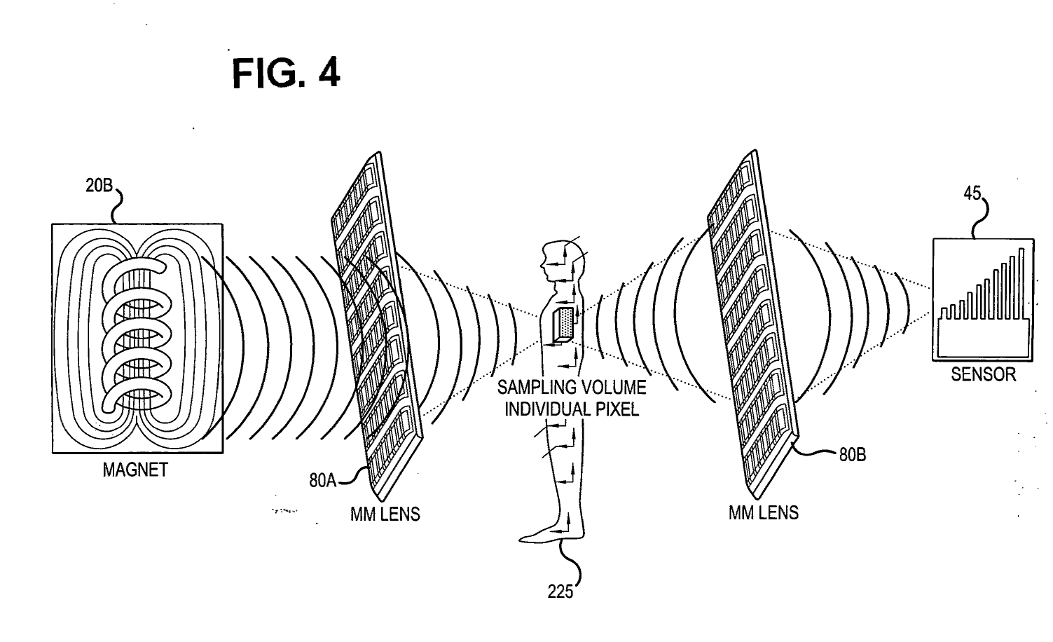

In an exemplary embodiment, the metamaterials lens is used to concentrate an ultra low magnetic field produced by source 20 to the person of interest as well as concentrate back the magnetic signature from the person to the detector 40. FIG. 4 is an exemplary Portable Bio-Magnetic Imager according to an embodiment of the present invention illustrated in FIG. 3. The Imager in FIG. 4 is not drawn to scale.

A patient 225 to which the contrast agent 30 is applied is placed between two metamaterials (MM) lenses 80A and 80B, where one metamaterials lens is located between the source magnet 20B and contrast agent 30, and a second metamaterials lens is placed between the detector 40 (which includes a detector sensor 45, which can be a cantilevered magnetorestrictive MEMS sensor in an exemplary embodiment) and contrast agent 30. An exemplary metamaterials lens for use in the portable Imager 200 provides a greater than 5× improvement to the processed signals associated with subject 225.

The incorporation of the metamaterial lens with the source and detector of the Portable Bio-Magnetic Imager 200 of the present invention enhances the performance of the Portable Bio-Magnetic Imager in two ways.

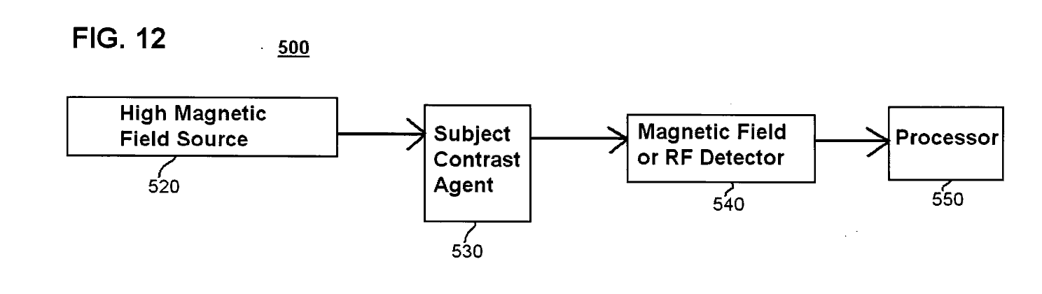

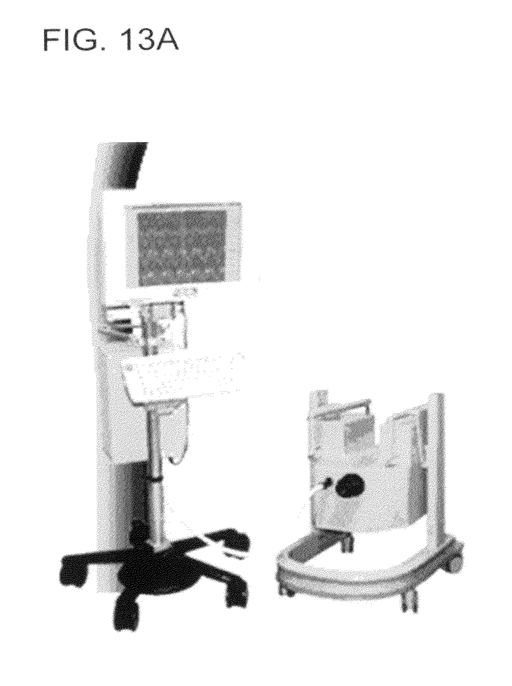

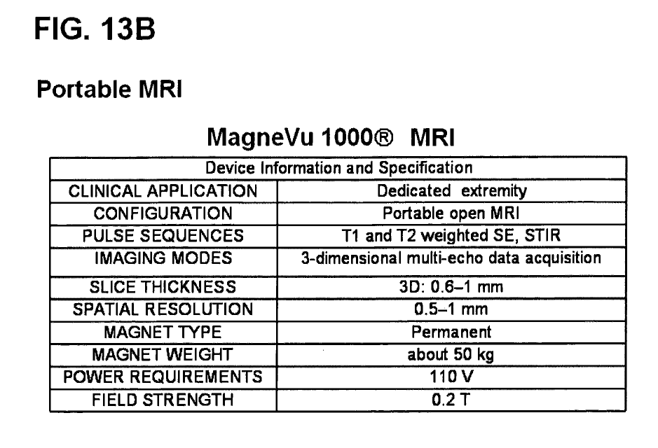

First, the metamaterials lens(es) better concentrates the input and output magnetic signal, and therefore the stand off distance from the area of interest within a subject (i.e., how far away from the Imager device the subject can be placed, whereby the Imager still performs imaging of the subject's organs/lesions) and the distance between the device and the person can be increased without decreasing the ability of the Bio-Magnetic Imager to image the area of interest within the person. Thus, while in conventional imaging systems, such as the ones illustrated in FIGS. 12 and 13A the subject has to be in direct contact with the device in order to obtain an image, a subject imaged by the Portable Bio-Magnetic Imager 200 of the present invention does not have to be in direct contact with the device in order to obtain an image. Thus, the Portable Bio-Magnetic Imager 200 provides significant flexibility for positioning of the subject relative to the imaging device.

Secondly, a metamaterials lens placed on the detector 40 or in the proximity of the detector 40 will decrease the need for extensive shielding from stray magnetic fields, since the signal from the anatomic area of interest will be concentrated more strongly back from that area of interest, thus improving the signal to noise ratio.

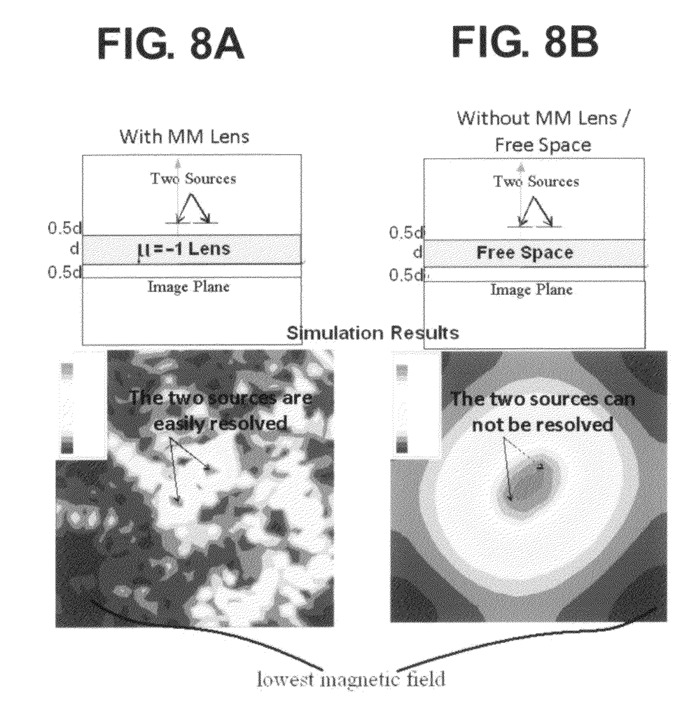

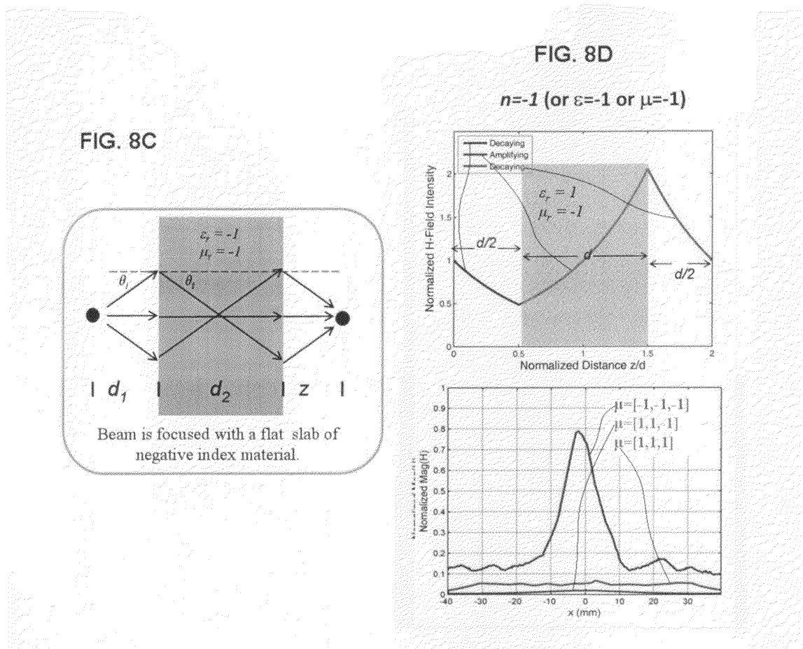

Details of an exemplary metamaterials lens are presented in FIGS. 8A-8D, 9A-9E, 10A-10B and 11A-11B which are described in more detail in the following pages.

In an exemplary embodiment of the present invention, a Portable Bio-Magnetic Imager 200A of the present invention includes 3 main components: a detector component, nanoparticles as the contrast agent 30, and a metamaterials lens. The detector component may be a low magnetic field detector in the range of sub-μT, which operates at room temperature and provides high sensitivity comparable to, or higher than, the sensitivity of a cooled SQUID device. The nanoparticles may be Ceria nanoparticles, which enhance performance of the Imager to perform very localized detection of brain injuries. The metamaterials lens enhances and concentrates the signal to the brain, and from the brain injury area to the detector, so that all signals from a localized area in the brain are received by the detector. Shielding, which is needed in conventional MRI imagers to remove external magnetic background and noise from detector and improve the SNR, is not needed for the Portable Bio-Magnetic Imager of the present invention, because the metamaterials lens effectively concentrates the signals from the brain injury area without the aid of shielding.

In another exemplary embodiment, the optics module 80 uses a hyperspectral metamaterials lens solution. The magnetically hyperspectral device is either a tunable metamaterials lens or a stacking of metamaterials lenses designed for specific frequencies and which can be turned on and off in order to probe at different frequencies. Such magnetically hyperspectral solution may surpass the performance of one metamaterials lens.

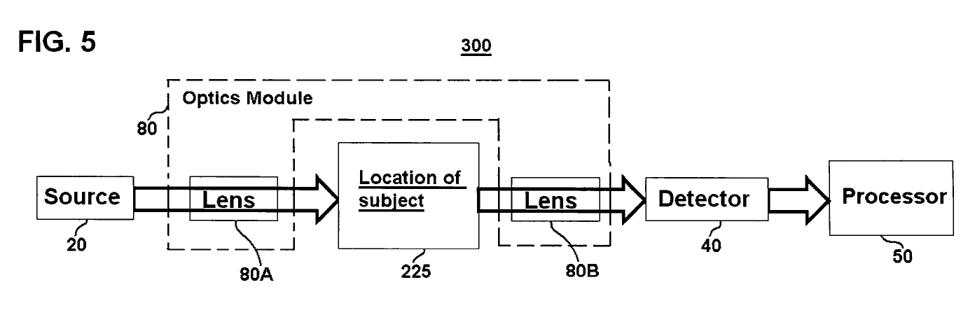

FIG. 5 is a block diagram of a Portable Bio-Magnetic Imager 300 according to another embodiment of the present invention. The Imager 300 includes a source 20, a detector 40, optics module 80, and processor 50, but does not include a contrast agent 30, because the metamaterials lens(es) 80A and/or 80B provide sufficient resolution, sensitivity and signal to noise ratio to concentrate the field into subject 225, and then subsequently into the detector 40 to detect TBI without the use of a contrast agent. The Imager may have two or more metamaterials lenses 80A and 80B placed between the source 20 and the subject 225, and between the subject 225 and the detector 40, respectively. In another embodiment, the Imager may have only one metamaterials lens 80A placed between source 20 and subject 225. In yet another embodiment, the Imager may have only one metamaterials lens 80B placed between subject 225 and detector 40. In another embodiment, the Imager 300 has only one metamaterials lens which is placed so as to both concentrate an ultra low magnetic field produced by source 20 to the subject 225, and concentrate back the magnetic signature from the subject 225 to the detector 40.

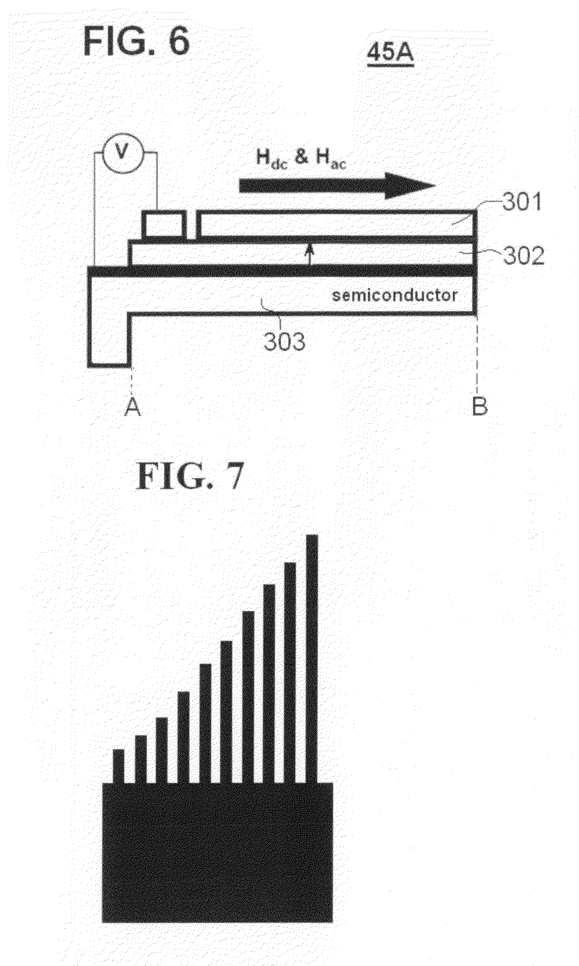

FIG. 6 illustrates a sensor 45A which operates at room temperature and may be used as a detector component in a detector 40 of a Portable Bio-Magnetic Imager according to embodiments of the present invention illustrated in FIGS. 1-5. The sensor of FIG. 6 is a magnetorestrictive sensor which includes a magnetoelectric multilayer portion including layers 301, 302 and 303. Layer 303 is a semiconductor material such as silicon.

In an exemplary embodiment of the sensor 45A, layer 301 may be a FeGa layer and layer 302 may be a piezoelectric material such as, for example, PZT. In the exemplary embodiment, the length of the sensor between points A and B is ˜20 mm, the cantilever thickness is on the order of 10's of microns, the thickness of layer 301 is ˜1.5 micron and the thickness of layer 302 is ˜1.5 micron.

Exemplary magnetorestrictive sensors that may be used as a sensor 45A in the Portable Bio-Magnetic Imager of the present invention are described in US Patent Application Publication US 2007/0252593 A1 (U.S. Pat. No. 7,345,475) by Takeuchi et al, the entire contents of this patent being hereby incorporated by reference.

The sensor illustrated in FIG. 6 is a magnetorestrictive sensor that operates at room temperature and can replace cryo-cooled SQUID based MRI systems, to reduce power usage and packaging size and volume. Unoptimized sensors have already shown ability to detect sub-μT magnetic fields. Optimization of the sensor performance has also been achieved, bringing the sensitivity even lower to further enhance the imaging capabilities of the Portable Bio-Magnetic Imager of the present invention. A Portable Bio-Magnetic Imager 100, 200 or 300 of the present invention in which Ceria nanoparticles are used and magnetorestrictive sensors that operate at room temperature are included in the detector allow for enhanced imaging in any field location, coupled with the ability to identify potential TBI damage that is currently difficult to diagnose even in large state-of-the-art MRI set-ups.

FIG. 7 illustrates a MEMS device including multiple cantilever devices for use in a Portable Bio-Magnetic Imager according to an embodiment of the present invention. The MEMS device of FIG. 7 can be used as a detector component 45 in the detector 40.

FIG. 8A illustrates imaging performance when a metamaterials lens is used according to an embodiment of the present invention, and FIG. 8B illustrates comparative imaging performance without a metamaterials lens. As can be seen in FIGS. 8A and 8B, two sources which cannot be resolved when a metamaterials (MM) lens is not used, are easily resolved when the imaging is performed using the metamaterials lens.

FIGS. 8C and 8D illustrate wave propagation in an exemplary metamaterial lens used in a Portable Bio-Magnetic Imager according to an embodiment of the present invention. The exemplary metamaterials lens in FIGS. 8C and 8D is described in publication “Negative Refraction Makes a Perfect Lens”, by Pendry, Physical Review Letters, Vol. 85 (18), October 2000, pp. 3966-3969, the entire contents of this publication being hereby incorporated by reference. The wave propagation patterns in FIGS. 8C and 8D are for a Negative Index Metamaterial (NIM) with n or μ=−1 (ε=μ=−1) metamaterials lens. Metamaterials enable enhanced imaging performance with a decreased need for shielding and field strength, and increased proximity to subject.

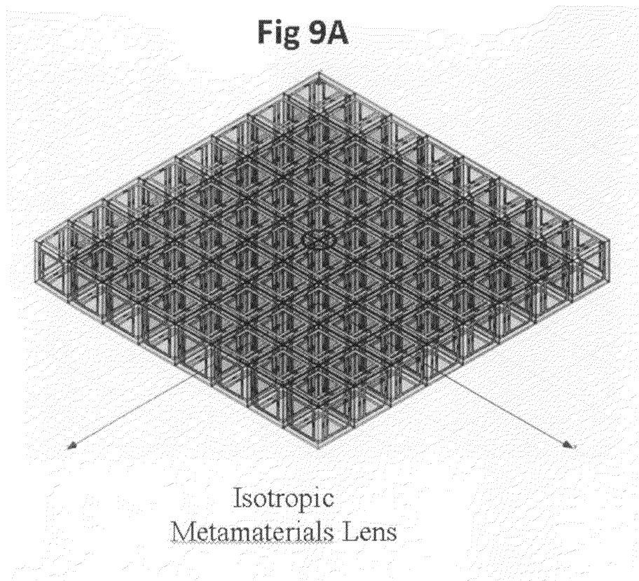

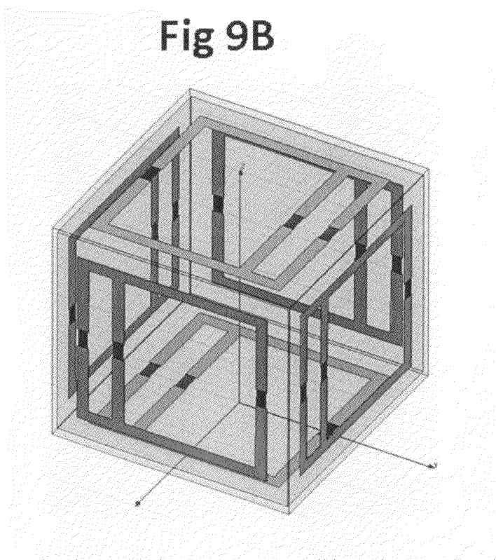

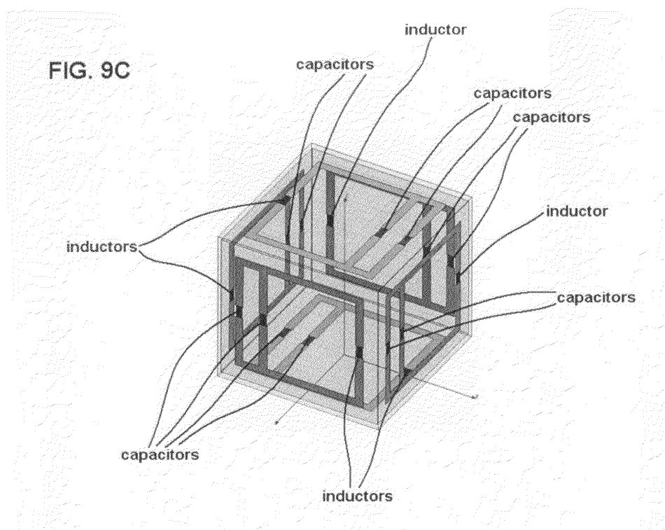

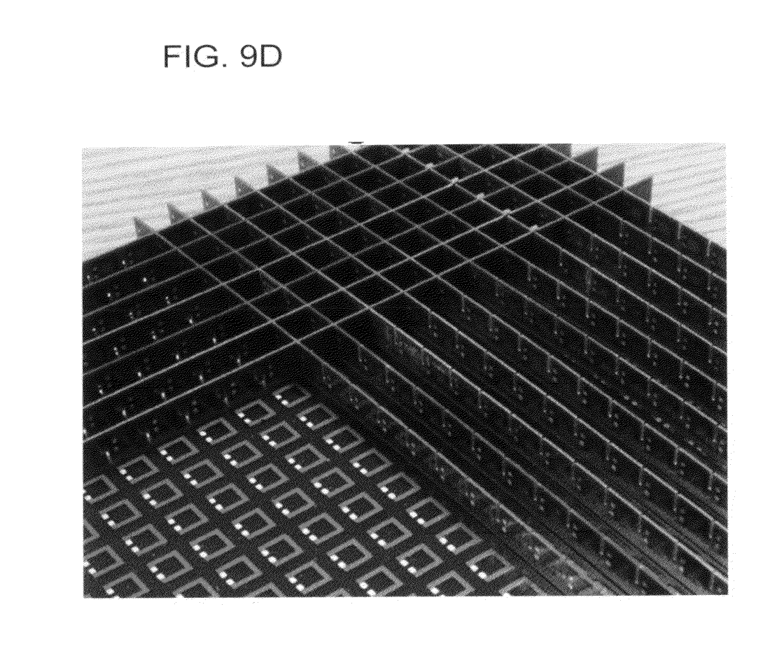

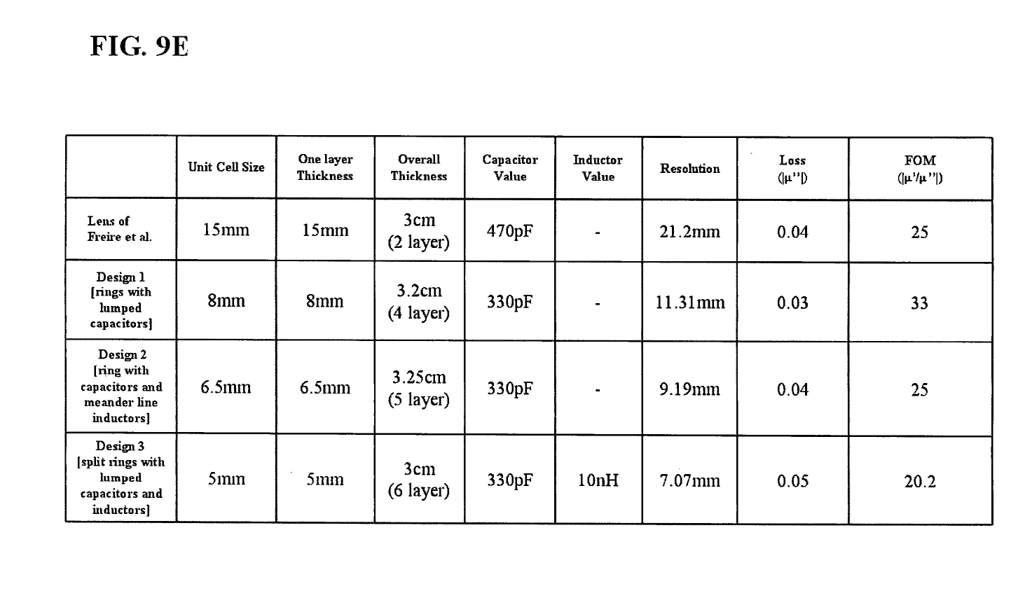

FIGS. 9A, 9B, 9C and 9D illustrate exemplary isotropic metamaterials lenses for use in a Portable Bio-Magnetic Imager according to an embodiment of the present invention. The metamaterials lens illustrated in FIGS. 9A-9D is an isotropic metamaterials lens (FIG. 9A) which includes multiple unit cells (FIG. 9B). Each unit cell illustrated in FIG. 9B includes rings with lumped capacitors and inductors. FIG. 9C, which illustrates the same unit cell as FIG. 9B, shows the location of the lumped capacitors and inductors. FIG. 9D illustrates the partially fabricated lens of FIG. 9A.

FIG. 9E illustrates details and performance of metamaterials lenses included in a Portable Bio-Magnetic Imager according to an embodiment of the present invention. The lens in the first row of the table is disclosed in publication “Experimental Demonstration of a μ=−1 Metamaterials Lens for Magnetic Resonance Imaging”, by Freire et al., Applied Physics Letters, 93, 231108, (2008), the entire contents of this publication being hereby incorporated by reference.

Designs 1, 2 and 3 (last 3 rows in the table) are metamaterials lenses designed for inclusion in the Portable Bio-Magnetic Imager of the present invention. The Design 1 lens includes rings with lumped capacitors. The Design 2 lens includes a ring with capacitors and meander line inductors. In a meander line antenna, the wire is continuously folded to reduce the resonant length. Increasing the total wire length in an antenna of fixed axial length lowers its resonant frequency.

The Design 3 lens includes split rings with lumped capacitors and inductors. An SRR (split ring resonator) element is an electromagnetic analog of an LC circuit, in which the ring acts as an inductor and the gap as a capacitor. As a gap is brought into the ring to build a split ring configuration, the ring geometry becomes an open boundary instead of a closed one.

The last column in the table illustrates figures of merit (FOM) for lens performance. The lenses of Designs 1-3 have different resonant structure forms, and differ from the lens of Freire et al. in their arrangement of elements (capacitors and inductors) on the individual unit cells. The arrangement of elements in the unit cells determines the design for a lens and the form of its resonant structure.

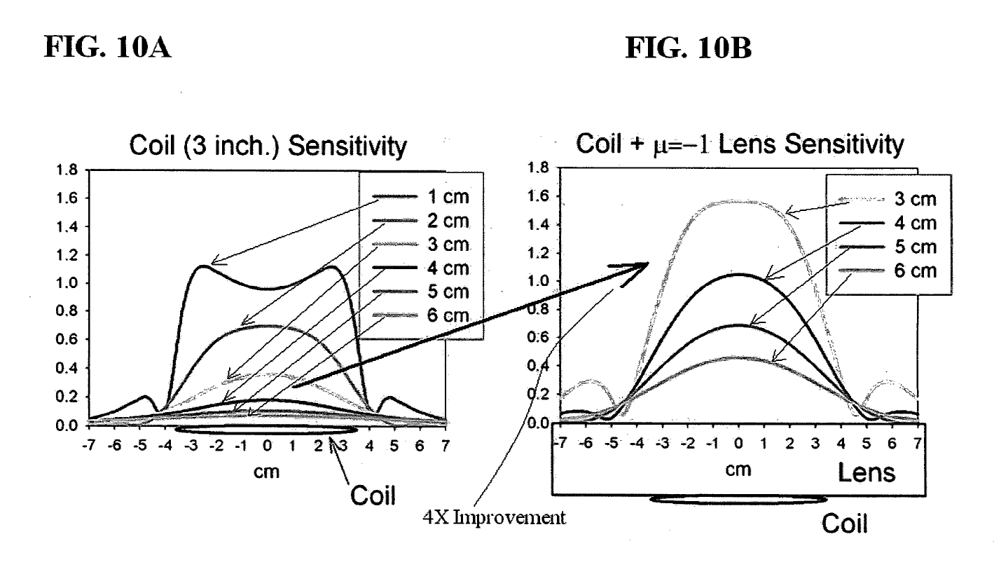

FIGS. 10A and 10B illustrate calculated sensitivity of a standard surface coil without (FIG. 10A) and with (FIG. 10B) a metamaterials lens which can be used in the Portable Bio-Magnetic Imager of the present invention. As can be seen in FIG. 10B, the addition of the metamaterials lens achieves a 4× signal improvement. The metamaterials lens used to generate the graph in FIG. 10B is described in the above mentioned publication “Experimental Demonstration of a μ=−1 Metamaterials Lens for Magnetic Resonance Imaging” by Freire et al., the entire contents of which are hereby incorporated by reference.

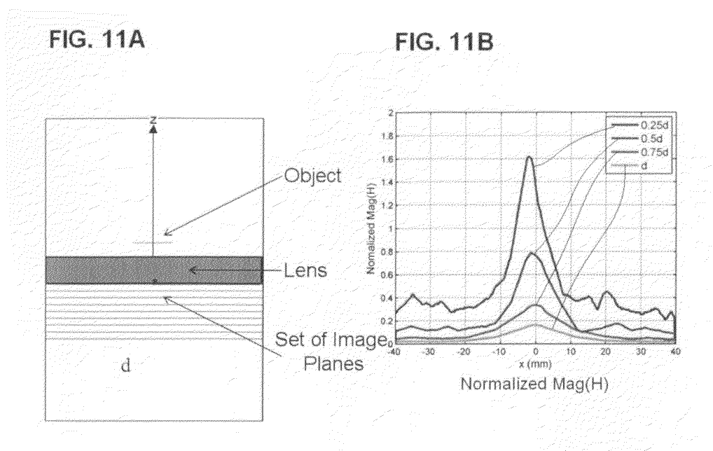

FIGS. 11A and 11B illustrate the change in normalized magnetic field intensity with a change in distance from an object to be imaged with a metamaterials lens used in a Portable Bio-Magnetic Imager according to an embodiment of the present invention. The physical setup for the measurements is shown in FIG. 11A for various image planes. The dimension “d” is the thickness of the metamaterials lens. The lens thickness can be engineered depending on the application, and the lens may include multiple layers.

Current MRI techniques are based on the magnetic resonance of the hydrogen proton. The present invention uses the fact that magnetic resonance can be tuned to specific elements. The frequency response will then change, based on applied field strength, by orders of magnitude. Metamaterials may enable precise tunability in the input/output signal of the Imager of the present invention, allowing for imaging to be tuned to specific elements other than hydrogen. Tunability may be provided by tunable elements included in/on the lens, or by a stacking of metamaterials lenses where each lens is tuned to a specific frequency or frequency range and has a narrow operating bandwidth, and each metamaterials lens can be selected based on the desired frequency response, by tuning through the field range. Thus, the resonance of the Imager can be switched through an entire field range. The detector is also designed to detect in multiple frequencies or frequency ranges. Currently, no other imaging technique has the capability to enable precise tunability while allowing for imaging to be tuned to specific elements other than hydrogen.

The range or magnitude of magnetic fields from the source, and the range of spatial dimensions of detector cantilevers (for example, lengths of various cantilevers for a detector such as the one illustrated in FIG. 7) can be selected in connection with the resonant frequencies to be detected by the Imager of the present invention, to improve tunability of the device.

The Portable Bio-Magnetic Imager of the present invention may be arranged in a hemisphere array, or in a portable sensor array such as a vest, to obtain detailed spatial information from multiple locations of a subject which are within relevant sensing distance from the sensors in sensor array of the Imager.

The Imager of the present invention can be used to select resonance signals based on the external magnetic field strength as well as frequency of detector and/or frequency of a device used to interrogate the sample/subject in order to obtain information. The Imager of the present invention may also be used in connection with, or combined with, state-of-the art MRI and NMR systems. In an exemplary embodiment, the resonance of the Imager of the present invention can be selected based on the external magnetic field strength as well as a frequency of an RF coil included in the detector and/or frequency of an RF gradient coil used to interrogate the sample/subject in order to obtain information.

The Bio-Magnetic Imaging device of the present invention has multiple advantages over state-of-the art imagers. The Portable Bio-Magnetic Imager of the present invention provides tunability of the input magnetic field with reduced need for power, and is a broader band device. The Imager also exhibits selectivity of the detector to specific frequencies across a broad band without loss of sensitivity. The metamaterials lens in the Imager acts as a resonant device having a relatively narrow bandwidth, which can therefore act as a filter as well as a concentrator. Metamaterials lenses in the Imager can also be tuned, and can be used in a broad magnetic field range including μT, 0.1 T, and Tesla size magnetic fields. Due to the lensing effect (both in input field and detected field), enhanced signal gathering from a target may decrease the need for extensive shielding and allow for larger distances to target, for stand off detection. Therefore, a subject imaged with the Imager of the present invention does not have to be in direct contact with the detector of the Imager, and could be located, in an exemplary embodiment, at a distance in the range of 1 meter from the detector.

The Imager of the present invention has the ability to specifically tune, which allows for differentiation of multiple material types, tissues, etc. Ceria nanoparticles used as “contrast agents” selectively congregate around points of damage before the damage points become large enough to reach the resolution limit of another imaging technique, thus giving valuable information about internal trauma earlier on.

Simulations and preliminary testing of individual components of the Portable Bio-Magnetic Imager have been performed. These include simulations of the metamaterials lens. Also, a single scanning sensor was used to simulate the sensor array and sensor sensitivity, and behavior of the nanoparticle contrast agent for magnetic behavior.

The Portable Bio-Magnetic Imager of the present invention is truly portable and has the ability to diagnose mild to moderate TBI hours before other conventional techniques can detect any brain damage. The Portable Bio-Magnetic Imager of the present invention can be physically transported by one person, or carried in a cart. The form factor with which the device may be integrated (a helmet-like form factor, for example) is smaller and more compact than any other currently available diagnostic imaging technique/devices. When the device is integrated in a helmet-like form factor, the source, metamaterials lenses (optics module) and detector are included in the helmet, to detect localized damage in the brain of a subject by placing the helmet on the subject's head.

Inclusion of a metamaterials lens has already been shown to give a 10× signal improvement in simulations, and a 4× signal improvement has been experimentally shown. A magnetically hyperspectral metamaterials device/solution may be used, which may surpass the performance of one metamaterials lens.

The Portable Bio-Magnetic Imager of the present invention has the ability to perform imaging portably and on the field. The Portable Bio-Magnetic Imager of the present invention can be used for clinical and emergency response and diagnostics, such as early detection of internal trauma. For example, the Portable Bio-Magnetic Imager can be used for early detection of brain injury and can perform diagnostic imaging in a battlefield. In Iraq, for example, wounded soldiers have to be taken by helicopter or caravan to a central location north of Iraq for any imaging diagnostics, which presents safety issues and a cost of transport for “non-life threatening” cases which are often not addressed soon enough. The Portable Bio-Magnetic Imager of the present invention can be used in various locations, in various climates, and is easily carried to any field location, to perform immediate imaging (such as TBI imaging) for detection of internal damage even when the damage is mild or moderate.

Other potential applications for the Portable Bio-Magnetic Imager of the present invention include underwater magnetic sensing and vehicle sensing, imaging for weapons, imaging for metal containers, magnetic imaging for border patrol, and advanced sensors.

Although aspects of the present invention have been described in the context of detection of brain injuries, it should be realized that the principles of the present invention are applicable to other types of anatomical detection besides brain injury detection or tissue injury detection, and to other types of signal detection besides anatomical detection. Furthermore, although detailed embodiments and implementations of the present invention have been described above, it should be apparent that various modifications are possible without departing from the spirit and scope of the present invention.

We claim:

1. An imager, said imager comprising:
a field source capable of generating a magnetic field directed to a subject;
a contrast agent applied to said subject, said contrast agent selectively seeking out an area in said subject, wherein said area also receives said magnetic field; and
a low magnetic field detector arranged downstream from said field source, said low magnetic field detector being capable of detecting a low magnetic field associated with said area indicated by said contrast agent.

2. The imager according to claim 1, wherein said contrast agent includes nanoparticles.

3. The imager according to claim 1, further comprising a metamaterials lens which concentrates an ultra low magnetic field produced by said field source to said subject, and/or concentrates back a magnetic signature from said subject to said low magnetic field detector.

4. The imager according to claim 1, further comprising a hyperspectral metamaterials-lens which concentrates a magnetic field produced by said field source to said subject.

5. The imager according to claim 1, wherein said low magnetic field detector includes a magnetometer device.

6. The imager according to claim 5, wherein said magnetometer device is a magnetorestrictive sensor that operates at room temperature.

7. The imager according to claim 1, wherein said imager is a portable bio-magnetic imager used for early detection of internal brain trauma.

8. The imager according to claim 1, wherein a low magnetic field detected by said low magnetic field detector is a magnetic field on the order of sub-μT.

9. The imager according to claim 2, wherein the nanoparticles are Ceria nanoparticles which selectively congregate around points of damage in said subject.

10. An imager, said imager comprising:
a field source capable of generating a magnetic field directed to an area in a subject;
a low magnetic field detector arranged downstream from said field source, said low magnetic field detector being capable of detecting a low magnetic field signature associated with said area in said subject; and
a metamaterials lens arranged downstream from said field source, said metamaterials lens concentrating said magnetic field produced by said field source to said area in said subject, and/or concentrating back said magnetic signature from said area in said subject to said low magnetic field detector.

11. The imager according to claim 10, wherein said metamaterials lens concentrates said magnetic field produced by said field source and directed to said subject, and concentrates back said magnetic signature from said subject to said low magnetic field detector.

12. The imager according to claim 10, wherein said metamaterials lens is positioned between said field source and said subject, the imager further comprising a second metamaterials lens positioned between said subject and said low magnetic field detector and concentrating back said magnetic signature from said subject to said low magnetic field detector.

13. The imager according to claim 10, wherein said metamaterials lens is included in a hyperspectral metamaterials lens device which is a tunable metamaterials lens.

14. The imager according to claim 10, wherein said metamaterials lens is included in a hyperspectral metamaterials lens device which includes a stacking of metamaterials lenses designed for specific frequencies.

15. The imager according to claim 10, further comprising a contrast agent including nanoparticles which selectively seek out said area in said subject.

16. The imager according to claim 15, wherein said nanoparticles are Ceria nanoparticles which selectively congregate around points of damage in said subject.

17. The imager according to claim 10, wherein a low magnetic field detected by said low magnetic field detector is a magnetic field on the order of sub-μT.

18. The imager according to claim 10, wherein said low magnetic field detector includes a magnetometer device that operates at room temperature.

19. The imager according to claim 10, wherein said imager is a portable bio-magnetic imager and the subject is a human.

20. An imaging method, said method comprising:
generating a magnetic field directed to a subject;
indicating an area in said subject using a contrast agent including nanoparticles which selectively seek out said area in said subject; and
detecting a low magnetic field associated with said area indicated by said contrast agent.

21. The method according to claim 20, further comprising concentrating, with a metamaterials lens, said generated magnetic field to said subject, and concentrating back a magnetic signature from said subject to perform said detecting step.

22. The method according to claim 20, further comprising concentrating said generated magnetic field to said subject using a metamaterials-lens hyperspectral technique.

23. The method according to claim 20, wherein said detecting step detects said low magnetic field using a magnetorestrictive sensor that operates at room temperature.

24. The method according to claim 20, wherein said subject is a human and said method bio-magnetically images said subject for early detection of internal brain trauma.

25. The method according to claim 20, further comprising
concentrating, with a metamaterials lens, said generated magnetic field to said subject, and concentrating back a magnetic signature from said subject to perform said detecting step,
wherein said detecting step detects sub-μT magnetic fields using a sensor that operates at room temperature.

26. An imaging method, said method comprising:
generating a magnetic field directed to an area in said subject;
concentrating, using a metamaterials lens, said generated magnetic field to said area in said subject; and
detecting a low magnetic field signature associated with said area in said subject.

27. The method according to claim 26, further comprising:
concentrating back said low magnetic field signature from said subject using a second metamaterials lens, to perform said detecting step.

28. The method according to claim 26, further comprising:
concentrating back said low magnetic field signature from said subject using said metamaterials lens, to perform said detecting step.

29. The method according to claim 26, wherein said concentrating step is performed using a metamaterials lens hyperspectral tunable technique which performs said concentrating step at a plurality of frequencies.

30. The method according to claim 26, further comprising:
indicating an area in said subject using a contrast agent including nanoparticles which selectively seek out said area in said subject, and
wherein said detecting step detects a low magnetic field signature associated with a low magnetic field on the order of sub-μT.

31. The method according to claim 26, wherein said subject is a human and said method bio-magnetically images said subject for early detection of internal brain trauma.
